(19) United States
(12) Patent Application Publication
(10) Pub. No.: US 2019/0006156 A1
(43) Pub. Date: Jan. 3, 2019

(54) Plasma Processing Apparatus

(71) Applicant: Wintel Co., Ltd., Hwaseong-si (KR)

(72) Inventors: Sang-Hun SEO, Daejeon (KR); Sanghyun CHUNG, Hwaseong-si (KR)

(21) Appl. No.: 16/067,811

(22) PCT Filed: Jan. 4, 2017
(86) PCT No.: PCT/KR2017/000077

§ 371 Date: Jul. 2, 2018

(30) Foreign Application Priority Data
Jan. 8, 2016 (KR) 10-2016-0002508

(51) Int. Cl. H01J 37/32; H01L 21/683

(52) U.S. Cl. CPC H01J 37/32642; H01L 21/6833; H01J 37/32724; H01L 21/67069; H01J 37/32091; H01J 37/3211; H01J 2237/334

(57) ABSTRACT

A plasma processing apparatus includes an electrostatic chuck configured to adsorb and hold a wafer, a focus ring disposed to surround an upper edge of the electrostatic chuck, an insulating tube disposed to cover a side surface of the electrostatic chuck, and a conductive tube disposed to cover the insulating tube.

### CROSS-REFERENCE TO RELATED APPLICATIONS

This application is a continuation of and claims priority to PCT/KR2017/000077 filed on Jan. 4, 2018, which claims priority to Korea Patent Application No. 10-2016-0002508 filed on Jan. 8, 2016, the entireties of which are both hereby incorporated by reference.

### TECHNICAL FIELD

The present disclosure relates to plasma processing apparatuses and, more particularly, to a focusing ring of a plasma processing apparatus which holds a wafer using an electrostatic chuck.

### BACKGROUND

Conventionally, a dry etching process is one of semiconductor manufacturing processes and is a process of forming a fine pattern on a wafer by applying a high frequency between top and bottom electrode means spaced at regular intervals and injecting a process gas to generate plasma. A plasma dry etching apparatus configured to perform a dry etching process may independently control an ion concentration and ion energy, increase a process margin, and reduce a wafer damage.

In the plasma dry etching apparatus, an electrostatic chuck is used to hold a wafer and a focus ring is provided around the electrostatic chuck. A portion of the focusing ring is formed at the same height as the electrostatic chuck. Thus, a wafer on which an etching process is performed is placed over the electrostatic chuck and the focusing such that they overlap each other. In general, the focusing is formed of silicon and is used to concentrate plasma on the wafer or increase an effective area of a bottom electrode.

The focusing is disposed below and around a substrate to limit plasma to an area directly adjacent to the substrate and on the substrate and includes a silicon or ceramic material etched by an etching gas.

When the focus ring is formed of silicon, the electrostatic may be protected by corrosion caused by plasma. The focus ring is consumed as etching is performed, is gradually worn out during an etching process, and changes process characteristics of a wafer edge after a certain period time. For this reason, the focus ring needs to be replaced. A focus ring, which is a consumable component, incurs lots of cost and reduces an equipment utilization rate depending on replacement of the focus ring. Thus, a focus ring having a novel structure is required to reduce a replacement cycle of the focus ring.

When the focus ring is formed of a ceramic material, a time-dependent etch rate is greater than that of silicon. The focus ring is formed of a dielectric material and results in distortion of a sheath to cause distortion (or tilt) of a wafer outer pattern.

### SUMMARY

An objective of the present disclosure is to ensure etch reliability of a wafer edge and extend the life of a focus ring by changing a structure and a material of the focus ring.

A plasma processing apparatus according to an example embodiments of the present disclosure includes an electrostatic chuck configured to adsorb and hold a wafer, a focus ring disposed to surround an upper edge of the electrostatic chuck, an insulating tube disposed to cover a side surface of the electrostatic chuck, and a conductive tube disposed to cover the insulating tube. The focus ring is disposed to extend over an electrostatic depression depressed in a ring shape at an edge of the electrostatic chuck, an upper end of the insulating tube, and an upper end of the conductive tube. The focus ring includes an external ring which is formed of an insulator and an internal conductive ring which is buried in the external ring. The external ring includes a first external ring which has a first height, a second external ring which has the same bottom surface as the first external ring and gradually increases in height to have an inclined surface, and a third external ring which has the same bottom surface as the second external ring and has a second height. The internal conductive ring includes a first internal conductive ring which is buried in the first external ring and extends flat, a second internal conductive ring which is continuously connected to the first internal conductive ring to extend to be inclined and is buried in the second external ring, and a third internal conductive ring which is continuously connected to the second internal conductive ring, extends flat, and is buried in the third external ring. The internal conductive ring is capacitively coupled to RF power applied to the electrostatic chuck to adjust a voltage structure of a sheath of plasma which is in contact with the focus ring. The wafer is disposed to extend over a top surface of the first external ring. A distance between a top surface of the external ring and a top surface of the internal conductive ring is constant.

In example embodiments, the focus ring may further include a ring-shaped focus ring coupling portion protruding downwardly from a bottom surface of the external ring. The focus ring coupling portion may be inserted to be fixed in a ring-shaped depression formed on a top surface of the insulating tube.

In example embodiments, the distance between the top surface of the external ring and the top surface of the internal conductive ring may be less than or equal to 3 millimeters.

In example embodiments, the distance between the top surface of the external ring and the top surface of the internal conductive ring may be less than or equal to a thickness of a dielectric material disposed on an RF electrode included in the electrostatic chuck.

A plasma processing apparatus according to another example embodiment of the present disclosure includes an electrostatic chuck configured to adsorb and hold a wafer, a focus ring disposed to surround an upper edge of the electrostatic chuck, an insulating tube disposed to cover a side surface of the electrostatic chuck, and a conductive tube disposed to cover the insulating tube. The focus ring is disposed to extend over an upper edge of the electrostatic chuck, an upper end of the insulating tube, and an upper end of the conductive tube. The focus ring includes an external ring which is formed of an insulator and an internal conductive ring which is buried in the external ring. The external ring includes a first external ring which has a first height, a second external ring which has the same top surface as the first external ring and has a second height greater than the first height. The internal conductive ring includes a first internal conductive ring which is buried in the first external ring and is flat, a second internal conductive ring which is continuously connected to the first internal conductive ring and is buried in the second external ring, and a third internal conductive ring which extends perpendicularly at a boundary between the first internal conductive ring and the second internal conductive ring and is buried in the second external ring. The internal conductive ring is capacitively coupled to RF power applied to the electrostatic chuck to adjust a voltage structure of a sheath of plasma which is in contact with the focus ring. A distance between a top surface of the external ring and a top surface of the first and second internal conductive rings is constant.

In example embodiments, the focus ring may further include a ring-shaped focus ring coupling portion protruding downwardly from a bottom surface of the second external ring. The focus ring coupling portion may be inserted to be fixed in a ring-shaped depression formed on a top surface of the insulating tube.

In example embodiments, the distance between the top surface of the external ring and the top surface of the first and second internal conductive rings may be less than or equal to 3 millimeters.

In example embodiments, the distance between the top surface of the external ring and the top surface of the first and second internal conductive rings may be less than or equal to a thickness of a dielectric material disposed on an RF electrode included in the electrostatic chuck.

### BRIEF DESCRIPTION OF THE DRAWINGS

The present disclosure will become more apparent in view of the attached drawings and accompanying detailed description. The embodiments depicted therein are provided by way of example, not by way of limitation, wherein like reference numerals refer to the same or similar elements. The drawings are not necessarily to scale, emphasis instead being placed upon illustrating aspects of the present disclosure.

FIG. 1. is a cut perspective view of an electrostatic chuck of a plasma processing apparatus according to an example embodiments of the present disclosure.

FIG. 2 is an enlarged view of the electrostatic chuck in FIG. 1.

FIG. 3 illustrates a plasma processing apparatus according to another example embodiment of the present disclosure.

### DETAILED DESCRIPTION

According to example embodiments of the present disclosure, a focus ring has etching resistance and includes an external ring which has etching resistance and is formed of an insulator and an internal ring which is buried in the external ring. The external ring may be formed of a material which is not etched to be consumed by an etching gas, and the internal ring reacts to plasma to provide a stable plasma sheath at the edge of a wafer.

The focus ring includes an internal conductive ring which electrically floats with respect to an external ring of ceramic material. The internal ring serves to establish an RF electric field to control a sheath structure in a wafer edge area. The RF electric field is received in the form of an antenna from an electrostatic chuck connected to an RF power supply. Accordingly, a surface area of the internal conductive ring and a thickness of ceramic between the electrostatic chuck and the internal conductive ring are important. To form a sheath having a similar shape to a sheath extending over a wafer at the edge of the wafer and in a focus ring region, it is determined in proportion to an electrostatic dielectric thickness between an RF electrode generating an RF bias on the electrostatic chuck and the wafer. When the electrostatic chuck dielectric material and a dielectric material constituting the external ring have different dielectric constants, a thickness of an electric material on the internal electrode ring is determined such that similar thickness effect occurs electrically.

A thickness of ceramic on the internal conductive ring has a great effect on a plasma sheath. The effect of forming the internal conductive ring at the focus ring is that a voltage and a structure of the plasma sheath in the focus ring region are controlled by creating functions of an RF electrode of the electrostatic chuck in the focus ring region.

The focus ring may control a voltage and a structure of the sheath at the wafer edge and in the focus ring region and minimize distortion of a pattern when the wafer edge is patterned. Moreover, the focus ring may minimize ion bombardment of particles which may be produced in the focus ring region during an etching process.

Example embodiments will now be described more fully with reference to the accompanying drawings, in which some example embodiments are shown. Example embodiments may, however, be embodied in many different forms and should not be construed as being limited to the embodiments set forth herein; rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements, and thus their description may be omitted.

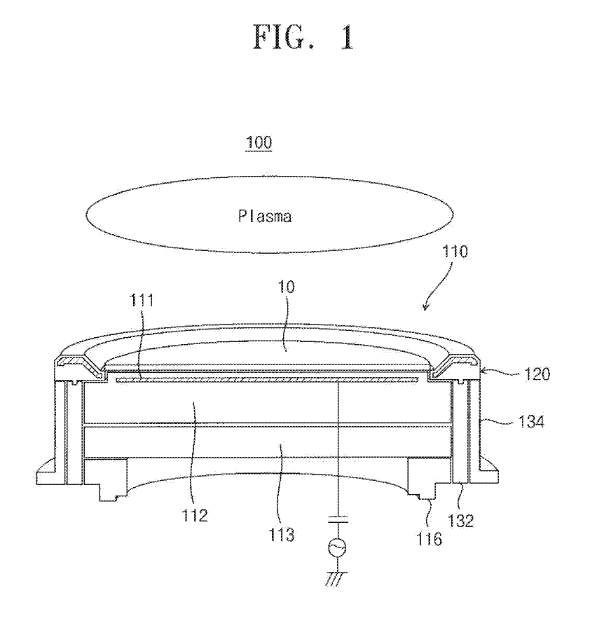

FIG. 1. is a cut perspective view of an electrostatic chuck of a plasma processing apparatus according to an example embodiments of the present disclosure.

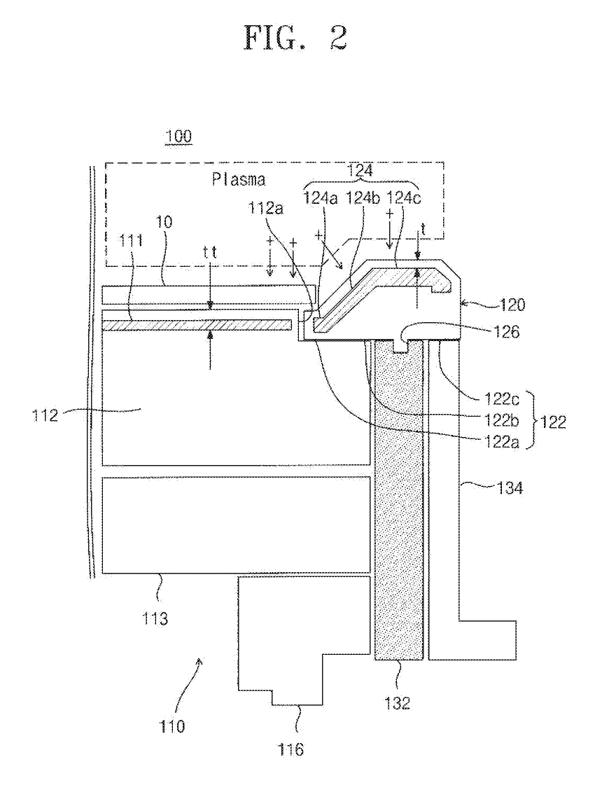

FIG. 2 is an enlarged view of the electrostatic chuck in FIG. 1.

Referring to FIGS. 1 and 2, a plasma processing apparatus 100 may include an electrostatic chuck 110 disposed inside a vacuum container (not shown). The electrostatic chuck 110 may include an electrostatic electrode supplied with a DC voltage from a DC voltage source through an RF filter and an RF electrode 111 supplied with RF power from an RF power supply through a capacitor. According to type of the electrostatic chuck 110, the electrostatic electrode and the RF electrode 111 may be separated from each other or may be fabricated as an integral part.

The plasma processing apparatus 100 includes the electrostatic chuck 110 configured to adsorb and hold a wafer 10, a focus ring disposed to surround an upper edge of the electrostatic chuck 110, an insulating tube 132 disposed to cover a side surface of the electrostatic chuck 110, and a conductive tube disposed to cover the insulating tube 132.

The plasma processing apparatus 100 may include a capacitively-coupled plasma generation electrode or an inductively-coupled plasma generation antenna spaced apart from an upper portion of the electrostatic chuck 1100 and supplied with power from a separate RF power supply. The inductively-coupled plasma generation antenna may be disposed outside a dielectric window disposed at the vacuum container.

The electrostatic chuck 110 may include the electrostatic chuck and the RF electrode 111, which may be fabricated as an integral part. The RF electrode 111 is supplied with RF power from the outside to generate capacitively-coupled plasma on the wafer 10. A sheath of the plasma accelerates ions to impinge on the wafer 10. Thus, the wafer 10 is etched by an etching gas.

A structure of the sheath at the center portion of the wafer 10 may be different from a structure of the sheath at the edge of the wafer 10. Accordingly, an internal electrode ring 124 formed of a conductor to perform similar functions to the RF electrode 111 is buried and disposed in the focus ring 120 such that a stable sheath is also formed at the edge of the wafer 10. The internal electrode ring 124 is supplied with power from the RF electrode 111 through capacitive coupling.

The focus ring 120 is disposed to extend over an electrostatic chuck depression 112a depressed in a ring shape at the edge of the electrostatic chuck 110, an upper end of the insulating tube 132, and an upper end of the conductive tube 134. The upper end of the insulating tube 132, the upper end of the conductive tube 134, and the electrostatic chuck 112a may be disposed on the same plane.

The electrostatic chuck 110 may include an electrostatic module 112, a temperature control module 113, and a support module 116. The electrostatic module 112 may include an electrostatic electrode and an RF electrode 111. The temperature control module 113 may include a heating block configured to maintain a temperature of the electrostatic module 112 constant and a cooling block to which a coolant flows. The support module 116 may support the electrostatic module 112 and the temperature control module 113 and include a coolant pipe path, a helium path, and an electrical wiring path.

The electrostatic chuck 110 may include the electrostatic depression 112a having a depressed upper edge. Accordingly, a portion of the focus ring 120 may be disposed to extend over the electrode 112a and the edge of the wafer 10 may be disposed to extend over an inner portion of the focus ring 120.

The focus ring 120 may include an external ring 122 formed of an insulator and an internal conductive ring 124 buried in the external ring 122. A material of the external ring 122 may be alumina, silicon carbide (SiC), ceramic or quartz. The internal conductive ring 124 may be formed of a high electroconductivity material such as metal, metal-alloy or graphite.

The external ring 122 includes a first external ring 122a which has a first height, a second external ring 122b which has the same bottom surface as the first external ring 122a and gradually increases in height to have an inclined surface, and a third external ring 122c which has the same bottom surface as the second external ring 122b and has a second height. An upper outer edge of the third external ring may be chamfered.

The internal conductive ring 124 may a first internal conductive ring 124a which is buried in the first external ring 122a and extends flat, a second internal conductive ring 124b which is continuously connected to the first internal conductive ring 124a to extend to be inclined and is buried in the second external ring 122b, and a third internal conductive ring 124c which is continuously connected to the second internal conductive ring 124b, extends flat, and is buried in the third external ring 122c.

The internal conductive ring 124 is capacitively coupled to RF power applied to the electrostatic chuck 110 such that the focus ring 120 is disposed to extend over a top surface of the first external ring 122a. To efficiently perform the capacitive coupling, it is preferable that a distance between the RF electrode 111 and the internal conductive ring 124 is short and a sufficient area.

A distance between a top surface of the external ring 122 and a top surface of the internal conductive ring 124 is constant. The internal conductive ring 124 may operate similar to the RF electrode 111 of the electrostatic chuck 110. Accordingly, a distance (t) between the top surface of the external ring 122 and the top surface of the internal conductive ring 124 may be substantially equal to or less than a thickness (tt) of a dielectric material on the RF electrode 111. In addition, the same dielectric material is preferably provided. That is, a ratio of a dielectric constant to a thickness (dielectric constant/thickness) may be constant. The distance (t) between the top surface of the external ring 122 and the top surface of the internal conductive ring 124 may be less than or equal to 3 millimeters (mm). Preferably, the distance (t) between the top surface of the external ring 122 and the top surface of the internal conductive ring 124 may be between 1 mm and 3 mm.

Due to the structure of the focus ring 120, ions obliquely impinge not in a wafer direction but in a focus ring direction to minimize the wafer edge effect. When the external ring 122 is formed of an insulator having durability against an etching gas (e.g., alumina or the like), the life of the focus ring 120 may sufficiently extend.

The focus ring 120 may include a ring-shaped focus ring coupling portion 126 protruding downwardly from a bottom surface of the external ring 122. The focus ring coupling portion 126 may is inserted to be fixed in a ring-shaped depression formed on the top surface of the insulating tube 132.

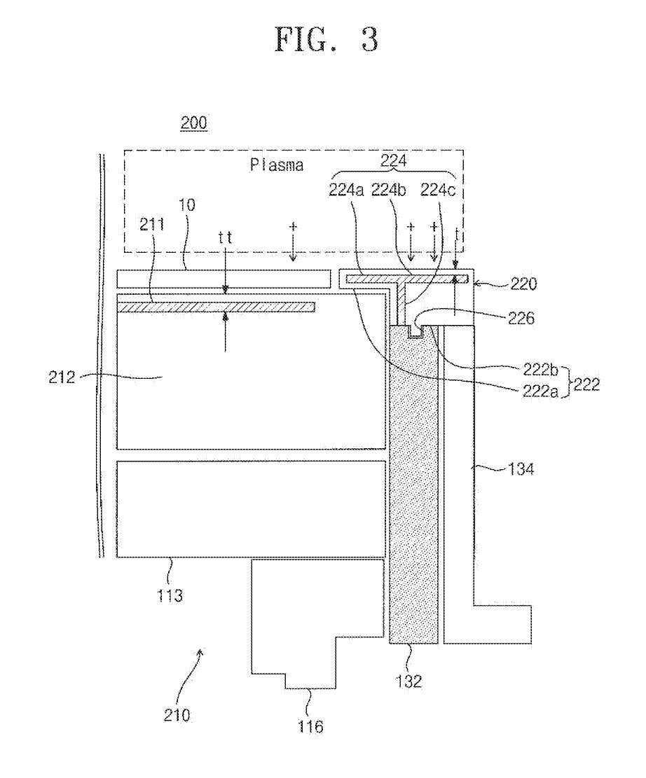

FIG. 3 illustrates a plasma processing apparatus according to another example embodiment of the present disclosure. In FIG. 3, explanations of the same components or parts as those shown in FIGS. 1 and 2 will be omitted.

Referring to FIG. 3, a plasma processing apparatus 200 includes an electrostatic chuck 210 configured to adsorb and hold a wafer 10, a focus ring 220 disposed to surround an upper edge of the electrostatic chuck 210, an insulating tube 132 disposed to cover a side surface of the electrostatic chuck 210, and a conductive tube 134 disposed to cover the insulating tube 132. The focus ring 220 may be disposed to extend over an upper edge of the electrostatic chuck 210, an upper end of the insulating tube 132, and an upper end of the conductive tube 134. the focus ring 220 includes an external ring 222 which is formed of an insulator and an internal conductive ring 224 which is buried in the external ring 222. The external ring 222 includes a first external ring 222a which has a first height and a second external ring 222b which has the same top surface as the first external ring 222a and has a second height greater than the first height.

The internal conductive ring 224 includes a first internal conductive ring 224a which is buried in the first external ring 222a and is flat, a second internal conductive ring 224b which is continuously connected to the first internal conductive ring 224a and buried in the second external ring 222b and is flat, a third internal conductive ring 224c which extends perpendicularly at the boundary between the first internal conductive ring 224a and the second internal conductive ring 224b and is buried in the second external ring 222b.

The internal conductive ring 224 is capacitively coupled to RF power applied to the electrostatic chuck 210 to adjust a voltage structure of a sheath of plasma which is in contact with the focus ring 220. A distance between a top surface of the external ring 222 and a top surface of the first and second internal conductive rings 224a and 224b is constant.

The focus ring 220 may include a ring-shaped focus ring coupling portion 226a protruding downwardly from a bottom surface of the second external ring 222b.

A top surface of the focus ring 220 may provide substantially the same height as a top surface of the wafer 10.

The focus coupling portion 226 may be inserted to be fixed in a ring-shaped depression formed on a top surface of the insulating tube 132.

A distance between a top surface of the external ring 222 and a top surface of the first and second internal conductive rings 224a and 224b may be less than 3 millimeters (mm).

As described above, a focus ring includes an external ring formed of an insulator and an internal conductive ring buried in the external ring and the internal conductive ring electrically interacts with an RF electrode. Thus, the above structure ensures etching reliability of a wafer edge and extends the life of the focus ring.

Although the present disclosure and its advantages have been described in detail, it should be understood that various changes, substitutions and alterations can be made herein without departing from the spirit and scope of the disclosure as defined by the following claims.

What is claimed is:

1. A plasma processing apparatus comprising:
an electrostatic chuck configured to adsorb and hold a wafer;
a focus ring disposed to surround an upper edge of the electrostatic chuck;
an insulating tube disposed to cover a side surface of the electrostatic chuck; and
a conductive tube disposed to cover the insulating tube,
wherein
the focus ring is disposed to extend over an electrostatic depression depressed in a ring shape at an edge of the electrostatic chuck, an upper end of the insulating tube, and an upper end of the conductive tube,
the focus ring includes an external ring which is formed of an insulator and an internal conductive ring which is buried in the external ring,
the external ring includes a first external ring which has a first height, a second external ring which has the same bottom surface as the first external ring and gradually increases in height to have an inclined surface, and a third external ring which has the same bottom surface as the second external ring and has a second height,
the internal conductive ring includes a first internal conductive ring which is buried in the first external ring and extends flat, a second internal conductive ring which is continuously connected to the first internal conductive ring to extend to be inclined and is buried in the second external ring, and a third internal conductive ring which is continuously connected to the second internal conductive ring, extends flat, and is buried in the third external ring,
the internal conductive ring is capacitively coupled to RF power applied to the electrostatic chuck to adjust a voltage structure of a sheath of plasma which is in contact with the focus ring,
the wafer is disposed to extend over a top surface of the first external ring, and
a distance between a top surface of the external ring and a top surface of the internal conductive ring is constant.

2. The plasma processing apparatus as set forth in claim 1, wherein
the focus ring further includes a ring-shaped focus ring coupling portion protruding downwardly from a bottom surface of the external ring, and
the focus ring coupling portion is inserted to be fixed in a ring-shaped depression formed on a top surface of the insulating tube.

3. The plasma processing apparatus as set forth in claim 1, wherein
the distance between the top surface of the external ring and the top surface of the internal conductive ring is less than or equal to 3 millimeters.

4. The plasma processing apparatus as set forth in claim 1, wherein
the distance between the top surface of the external ring and the top surface of the internal conductive ring is less than or equal to a thickness of a dielectric material disposed on an RF electrode included in the electrostatic chuck.

5. A plasma processing apparatus comprising:
an electrostatic chuck configured to adsorb and hold a wafer;
a focus ring disposed to surround an upper edge of the electrostatic chuck;
an insulating tube disposed to cover a side surface of the electrostatic chuck; and
a conductive tube disposed to cover the insulating tube,
wherein
the focus ring is disposed to extend over an upper edge of the electrostatic chuck, an upper end of the insulating tube, and an upper end of the conductive tube,
the focus ring includes an external ring which is formed of an insulator and an internal conductive ring which is buried in the external ring,
the external ring includes a first external ring which has a first height, a second external ring which has the same top surface as the first external ring and has a second height greater than the first height,
the internal conductive ring includes a first internal conductive ring which is buried in the first external ring and is flat, a second internal conductive ring which is continuously connected to the first internal conductive ring and is buried in the second external ring, and a third internal conductive ring which extends perpendicularly at a boundary between the first internal conductive ring and the second internal conductive ring and is buried in the second external ring,
the internal conductive ring is capacitively coupled to RF power applied to the electrostatic chuck to adjust a voltage structure of a sheath of plasma which is in contact with the focus ring, and
a distance between a top surface of the external ring and a top surface of the first and second internal conductive rings is constant.

6. The plasma processing apparatus as set forth in claim 5, wherein
the focus ring further includes a ring-shaped focus ring coupling portion protruding downwardly from a bottom surface of the second external ring, and
the focus ring coupling portion is inserted to be fixed in a ring-shaped depression formed on a top surface of the insulating tube.

7. The plasma processing apparatus as set forth in claim 5, wherein
the distance between the top surface of the external ring and the top surface of the first and second internal conductive rings is less than or equal to 3 millimeters.

8. The plasma processing apparatus as set forth in claim 5, wherein
the distance between the top surface of the external ring and the top surface of the first and second internal conductive rings is less than or equal to a thickness of a dielectric material disposed on an RF electrode included in the electrostatic chuck.
